(19) United States
(12) Patent Application Publication
(10) Pub. No.: US 2026/0018382 A1
(43) Pub. Date: Jan. 15, 2026

(54) SWITCHING CIRCUIT, AND IMPEDANCE TUNING NETWORK

(71) Applicant: Rohde & Schwarz GmbH & Co. KG, Muenchen (DE)

(72) Inventors: Adrian FRUEHAUF, Muenchen (DE); Gabor CZOBOR, Muenchen (DE)

(21) Appl. No.: 19/220,697

(22) Filed: May 28, 2025

(30) Foreign Application Priority Data
Jul. 12, 2024 (EP) 24 188 323.0

(51) Int. Cl. H01J 37/32

(52) U.S. Cl. CPC H01J 37/32183; H01J 37/32935

(57) ABSTRACT

A switching circuit for selectively closing or interrupting a radio frequency (RF) signal path includes a switchable element that is switchable between an on-state and an off-state. The switching circuit also includes a control circuit and a power supply circuit. The control circuit is configured to apply a control signal provided by the power supply circuit to the switchable element. The control signal includes a control voltage and/or a control current. The control circuit includes a first signal path that includes at least one first diode being configured to provide the control signal to the switchable element. The control circuit comprises a second signal path. The second signal path is arranged in parallel to the first signal path. The second signal path includes at least one second diode that is arranged with opposite polarity compared to the at least one first diode.

### CROSS-REFERENCE(S) TO RELATED APPLICATION(S)

This application claims priority to European Application No. 24 188 323.0, filed on Jul. 12, 2024, the entire disclosure of which is disclosed in its entirety herein.

### FIELD OF THE DISCLOSURE

Embodiments of the present disclosure generally relate to a switching circuit for selectively closing or interrupting an radio frequency (RF) signal path. Embodiments of the present disclosure further relate to an impedance tuning network.

### BACKGROUND

Certain RF applications require electronic switches that are capable of rapidly switching between an on-state and an off-state. Such an electronic switch usually requires a DC control signal delivered via a DC control signal path to engage the switching operation. This DC control signal or the DC control signal path needs to be isolated from the RF signal to prevent damage and/or unwanted interference. Accordingly, RF suppressing elements or components that perform this isolation or separation between DC and RF are required.

These RF suppressing elements become comparably large in size if the concerned RF voltages are high, such as several hundred volts. Furthermore, these RF suppressing elements usually act as an energy storage, which ultimately reduces the switching speed of the switching circuit. Moreover, the RF suppressing elements may be resistive and thus be associated with additional losses.

Thus, there is a need for a switching circuit for selectively closing or interrupting an RF signal path that provides an enhanced switching speed and/or reduced spatial requirements.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a switching circuit for selectively closing or interrupting a radio frequency (RF) signal path. In an embodiment, the switching circuit comprises a switchable element, wherein the switchable element is switchable between an on-state and an off-state. The switching circuit also comprises a control circuit and a power supply circuit. The control circuit is configured to apply a control signal provided by the power supply circuit to the switchable element, wherein the control signal comprises a control voltage and/or a control current. The control circuit comprises a first signal path, wherein the first signal path comprises at least one first diode being configured to provide the control signal to the switchable element. The control circuit also comprises a second signal path, wherein the second signal path is arranged in parallel to the first signal path. The second signal path comprises at least one second diode, wherein the at least one second diode is arranged with opposite polarity compared to the at least one first diode.

The switching circuit according to embodiments of the present disclosure is based on the idea to provide at least one pair of diodes in the two parallel signal paths, wherein the diodes are arranged with opposite polarity. As will be described in more detail below, the diodes may be connected to independent control signal sources or bias voltages.

In an embodiment, one of the diodes, namely the first diode, provides the control signal to the switchable element, wherein the control signal causes the switchable element to close the RF signal path, keep the RF signal path closed, interrupt the RF signal path, or keep the RF signal path interrupted.

In other words, the control signal provided to the switchable element via the at least one first diode may cause the switchable element to switch from the off-state to the on-state, remain in the on-state, switch from the on-state to the off-state, or remain in the off-state.

In an embodiment, the at least one second diode, which has opposite polarity compared to the at least one first diode, accelerates the switching at least from the on-state to the off-state, as the at least one second diode enables charge stored in the switchable element to be transported away from the switchable element quickly.

Further, using a diode, namely the first diode, to provide the control signal to the switching element allows to reduce the impedance of RF suppressing components in the control circuit, or to even omit these RF suppressing components completely.

As a result, less magnetic and/or electric energy is stored in these protective components during switching from the on-state to the off-state or vice versa, which further enhances the attainable switching speed.

Further, this allows to omit RF suppressing components that are physically large, i.e. that require a large volume, thereby reducing the spatial requirements of the switching circuit.

The inventors of the disclosed subject matter recognized that switching times attainable with the switching circuit according to embodiments of the present disclosure may be substantially smaller than for electronic switches known in the state of the art.

In an embodiment, switching times of the order of microseconds, or even below one microsecond are attainable.

Moreover, as diodes have a rather small residual capacity, the switching circuit provides a reduced detuning of an impedance of the RF signal path, for example in the off-state of the switchable element.

In an embodiment, the switching circuit may be configured for high voltages, i.e. voltages between approximately 100 V and 10 kV.

In an embodiment, the switchable element may be interconnected between an RF signal source and a reference potential, i.e. in the on-state of the switchable element the RF current flows to or from the reference potential.

According to an aspect of the present disclosure, the control circuit further comprises, for example, at least one RF suppressing element. In an embodiment, the at least one RF suppressing element is arranged in the first signal path, in the second signal path, and/or in series with the first signal path and the second signal path. In general, the at least one RF suppressing element is configured to dampen or completely block RF currents through the at least one first diode.

In an embodiment, in the on-state of the switching element, the proportion of the RF current flowing through the switchable element compared to the proportion of the RF current flowing through the at least one first diode can be set through the impedance of the RF suppressing element.

For example, the impedance, for example the inductance and/or resistance of the at least one RF suppressing element may be chosen such that a predefined percentage of the RF current flows through the switchable element, e.g. more than 50% or more than 75%.

Therein, it is to be understood that the impedance, for example the inductance, of the RF suppressing element can be chosen to be smaller than in the prior art, or the RF suppressing element can even be omitted. Thus, faster switching speeds are provided.

For example, the at least one RF suppressing element may be or comprise at least one resistor and/or at least one inductor. As another example, the at least one RF suppressing element may be or comprise an LC parallel circuit, i.e. a parallel circuit having at least one inductor and at least one capacitor.

However, it is to be understood that the at least one RF suppressing element may be or comprise any other suitable type of electronic circuitry being configured to dampen or block RF currents. For example, the at least one RF suppressing element may be purely resistive.

In an embodiment, the at least one RF suppressing element is arranged in the first signal path, wherein the at least one RF suppressing element is arranged in series with the at least one first diode. The advantages and properties of the at least one RF suppressing element described above likewise apply.

In another embodiment, the first signal path and the second signal path each are to connected to a common connection point, wherein the switchable element is connected to the common connection point. Accordingly, the control signal is provided to the switchable element via the first signal path and the common connection point. When switching from the on-state to the off-state, the switchable element may be discharged via the common connection point and the second signal path.

According to another aspect of the present disclosure, the switchable element, for example, is a diode. As diodes usually have a rather small residual capacity, influences of the switching circuit on an impedance of the RF signal path or of a circuit connected to the RF signal path are reduced, namely in the off-state of the switching element. In an embodiment, the switchable element is or comprises a PIN diode, a PN-Si diode, a PN-SiC diode, etc. However, it is to be understood that the switchable element may also be established as a field effect transistor (FET) or as another suitable type of electronic circuitry.

PIN diodes have a particularly small residual capacity, such that influences of the switching circuit on an impedance of the RF signal path or of a circuit connected to the RF signal path are minimized. Using SiC diode(s), the switching speed can be further enhanced and the manufacturing costs of the switching circuit can be reduced.

In an embodiment, the at least one first diode is a PIN diode, a PN-Si diode, or a PN-SiC diode, and/or wherein the at least one second diode is a PIN diode, a PN-Si diode, or a PN-SiC diode.

As explained above, PIN diodes have a particularly small residual capacity, such that influences of the switching circuit on an impedance of the RF signal path or of a circuit connected to the RF signal path are minimized.

Using PN-Si diode(s) or PN-SiC diode(s), the switching speed can be further enhanced and the manufacturing costs of the switching circuit can be reduced.

In an embodiment, the first signal path may comprise a plurality of first diodes. For example, the plurality of first diodes may be arranged in a series connection. This allows to employ a plurality of diodes that are, individually, more cost efficient, as the individual diodes do not have to meet the requirements of the switching circuit e.g. regarding a blocking voltage. Instead, it is sufficient that series connection of the plurality of first diodes meets these requirements. It has been recognized by the inventors of the present disclosure that employing a plurality of first diodes meeting these requirements together may be more cost-efficient than employing a single diode meeting the requirements.

For example, if the first signal path comprises a plurality of diodes, the individual diodes may be established as Si-diodes instead of PIN diodes or SiC diodes, wherein the Si-diodes are obtainable at reduced cost, thereby reducing the manufacturing costs for the switching circuit.

Alternatively or additionally, the second signal path may comprise a plurality of second diodes. For example, the plurality of diodes may be arranged in a series connection. This allows to employ a plurality of diodes that are, individually, more cost efficient, as the individual diodes do not have to meet the requirements of the switching circuit e.g. regarding a blocking voltage. Instead, it is sufficient that series connection of the plurality of second diodes meets these requirements. It has been recognized by the inventors of the present disclosure that employing a plurality of second diodes meeting the requirements together may be more cost-efficient than employing a single diode meeting the requirements.

For example, if the second signal path comprises a plurality of diodes, the individual diodes may be established as Si-diodes instead of PIN diodes or SiC diodes, wherein the Si-diodes are obtainable at reduced cost, thereby reducing the manufacturing costs for the switching circuit.

An aspect of the present disclosure provides, for example, that the power supply circuit comprises a first bias supply and a second bias supply. The first bias supply is connected to the first signal path and the second bias supply is connected to the second signal path. This enables to provide different bias voltages to the at least one first diode and to the at least one second diode. In other words, the first bias supply may be independent of the second bias supply.

In an embodiment, the first bias supply comprises a first half bridge. Alternatively or additionally, the second bias supply may comprise a second half bridge. Therein, the first half bridge and the second half bridge may be connected to different voltage sources being independent of each other. This way, different voltage levels for the first signal path and for the second signal path can be generated, for example wherein the different voltage levels may be generated with different timings.

In an embodiment, the second half bridge may provide an intermediate voltage level for switching the switchable element from the on-state to the off-state. This allows for a particularly fast switching between the on-state and the off-state.

In a static off-state of the switchable element, the second half bridge may provide a reverse bias voltage for the first diode, the second diode, and the switchable element. This further reduces the residual capacitance of the switching circuit, for example the residual capacitances of the first diode, the second diode, and/or the switchable element.

In an embodiment, the half bridges may each comprise or consist of a plurality of switches.

In an embodiment, the switch may comprise at least one transistor or a plurality of transistors, e.g. a bipolar transistor, an Insulated-Gate Bipolar Transistor (IGBT), an FET, a MOSFET (e.g. Si, SiC, GaN), or any other suitable type of transistor.

Alternatively or additionally, the half bridges each may comprise resistive and/or reactive components.

Embodiments of the present disclosure further provide an impedance tuning network. The impedance tuning network comprises at least one switching circuit according to any one of the embodiments described above.

Regarding the advantages and further properties of the impedance tuning network, reference is made to the explanations given above with respect to the switching circuit, which also hold for the impedance tuning network and vice versa.

Therein and in the following, the term “impedance tuning” is understood to denote altering the impedance of a certain circuit at a fixed or variable frequency and/or shifting an impedance characteristic of the circuit to another frequency.

According to an aspect of the present disclosure, the impedance tuning network comprises, for example, at least one impedance tuning circuit. In an embodiment, the impedance tuning circuit comprises at least one reactance and at least one switching circuit according to any one of the embodiments described herein. The at least one switching circuit is configured to selectively connect the at least one reactance to or into an RF signal path of the impedance tuning network. In other words, the at least one reactance can be connected to and/or into the RF signal path of the impedance tuning network by the at least one switching circuit, namely by switching the switchable element to its on-state. The at least one reactance can be disconnected from the RF signal path, namely by switching the switchable element to its off-state.

In an embodiment, the RF signal path (“RF bus”) may be a transmission line.

In an embodiment, the at least one reactance may be or comprise at least one capacitance and/or at least one inductance.

According to another aspect of the present disclosure, the impedance tuning network, for example, is established as an impedance matching network, for example for plasma processes or for an RF antenna. In an embodiment, an impedance of the impedance matching network can be adapted by selectively connecting the at least one reactance to or into an RF signal path of the impedance matching network.

In an embodiment, the RF antenna may be associated with an MRI application or with a communication device.

For plasma processes, the impedance matching network may be provided between an RF signal generator generating an RF signal for exciting plasma, i.e. for biasing, sourcing and/or striking the plasma, and a plasma process chamber. An impedance presented to the RF signal generator generating the RF signal can be adapted, namely adapted based on the impedance of the plasma varying over time.

For RF antennas, desired transmission and/or reception properties can be obtained by tuning the impedance of the impedance matching network connected to the RF antenna(s) appropriately.

According to a further aspect of the present disclosure, the impedance tuning network, for example, is configured to tune an impedance characteristic of a tunable filter. In an embodiment, the impedance tuning network may be configured to adapt the impedance characteristic of the tunable filter at a fixed frequency and/or shift the impedance characteristic of the tunable filter to another frequency. For example, the tunable filter may be a hopping filter employed in frequency hopping techniques.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a first embodiment of a switching circuit according to the present disclosure;

FIG. 2 schematically shows a second embodiment of a switching circuit according to the present disclosure;

FIG. 3 schematically shows a first embodiment of an impedance tuning network according to the present disclosure;

FIG. 4 schematically shows a second embodiment of an impedance tuning network according to the present disclosure; and

FIG. 5 schematically shows a third embodiment of an impedance tuning network according to the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

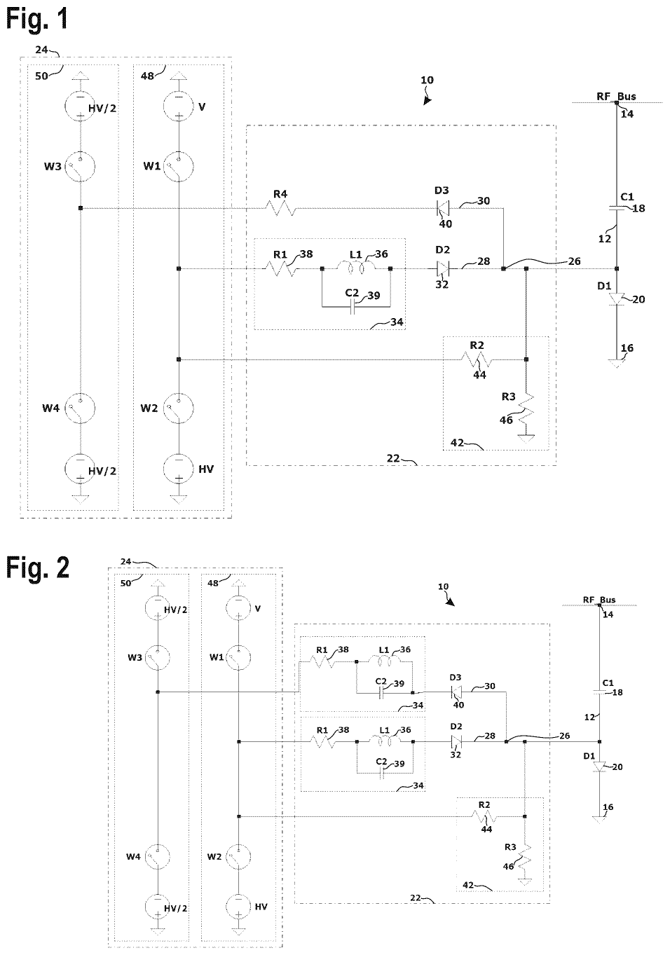

FIG. 1 schematically shows an example of a switching circuit 10 configured to selectively close or interrupt an RF signal path 12. In the embodiment shown in FIG. 1, the RF signal path 12 extends between an RF signal source 14 and a reference potential 16, wherein a reactance 18 is provided in the RF signal path 12. For example, the reactance 18 may be a capacitor or an inductor. However, it is to be understood that other configurations and/or topologies of the RF signal path 12 may be possible.

In the embodiment of FIG. 1, the switching circuit 10 comprises a switchable element 20 that is provided in the RF signal path 12. In general, the switchable element 20 is switchable between an on-state and an off-state. In the on-state, the RF signal path 12 is closed, such that an RF current can flow between the RF signal source 14 and the reference potential 16. In the off-state, the RF signal path 12 is interrupted, such that no RF current can flow between the RF signal source 14 and the reference potential 16.

In the example embodiment shown in FIG. 1, the switchable element 20 is established as a diode, for example as a PIN diode. Alternatively, the switchable element 20 may be established as any other suitable type of electronic component, such as a SiC diode, or as a field effect transistor (FET).

In the embodiment shown in FIG. 1, an anode of the switchable element 20 is connected to the RF signal source 14, while a cathode of the switchable element 20 is connected to the reference potential 16. However, the polarity of the switchable element 20 may also be reversed.

In an embodiment, the switching circuit 10 further comprises a control circuit 22 and a power supply circuit 24. The control circuit 22 comprises a common connection point 26 that is connected to the switchable element 20 upstream of the switchable element 20, i.e. at the point between the switchable element 20 and the RF signal source 14. In other words the common connection point 26 is connected to the anode of the switchable element 20, or to the cathode of the switchable element 20 if the polarity of the switchable element 20 is reversed.

In an embodiment, the control circuit 22 also comprises a first signal path 28 and a second signal path 30 that are each connected to the common connection point 26 and that extend parallel to each other. In an embodiment, the first signal path 28 comprises at least one first diode 32 that is arranged with the same polarity as the switchable element 20 with respect to the reference potential 16. Accordingly, a control signal provided by the power supply circuit 24 can be forwarded to the switchable element 20 via the first diode 32.

Therein, the control signal may be a control current and/or a control voltage.

In an embodiment, the at least one first diode 32 may be, for example, a PIN diode, a PN-Si diode, or a PN-SiC diode.

It is noted that the at least one first diode 32 may comprise a plurality of first diodes 32 that are arranged in a series connection. In this case, the plurality of first diodes 32 may be a PIN diode, a SiC diode, or a Si diode, respectively.

In an embodiment, the first signal path 28 may further comprise an RF suppressing element 34 that is arranged in a series connection with the at least one first diode 32. In general the RF suppressing element 34 is configured to dampen or completely block RF signals.

In the example embodiment of FIG. 1, the RF suppressing element 34 comprises an inductor 36, a resistor 38, and a capacitor 39. However, it is to be understood that any other suitable type of electronic circuitry may be used, for example only a resistor, only an inductor, only an LC parallel circuit, or any combination of these components.

Alternatively to the topology shown in FIG. 1, the RF suppressing element 34 may be arranged in series to the first signal path 28 and the second signal path 30, for example between the common connection point 26 and the RF signal path 12.

In an embodiment, the second signal path 30 comprises at least one second diode 40 that is arranged with opposite polarity compared to the switchable element 20 with respect to the reference potential 16. Accordingly, the at least one first diode 32 and the at least one second diode 40 are arranged with opposite polarities.

When switching the switchable element 20 from the on-state to the off-state, the at least one second diode 40 enables the connection of a reverse voltage pulse and/or current pulse to the switchable element 20, such that the switching speed is increased.

In an embodiment, the at least one second diode 40 may, for example, be a PIN diode, a PN-Si diode, or a PN-SiC diode.

It is noted that the at least one second diode 40 may comprise a plurality of second diodes 40 that are arranged in a series connection. In this case, the plurality of second diodes 40 may be a PIN diode, a SiC diode, or a Si diode, respectively.

In an embodiment, the control circuit 22 may further comprise a voltage divider 42 being connected to the common connection point 26, the reference potential 16, and the power supply circuit 24. For example, the voltage divider 42 may be a resistive voltage divider comprising a first resistor 44 and a second resistor 46, wherein the second resistor 46 is optional. The first resistor 44 is connected between the common connection point 26 and the power supply circuit 24, while the second resistor 46 is connected between the common connection point 26 and the reference potential 16.

In the off-state of the switchable element 20, the voltage divider 42 ensures a controlled distribution of a blocking voltage to the switchable element 20 and to the at least one first diode 32.

It is noted that the switching circuit 10 described above and hereinafter may alternatively be implemented with all of the polarities of the switchable element 20, the at least one first diode 32, and the at least one second diode 40 reversed.

In an embodiment, the power supply circuit 24 comprises a first bias supply 48 that is connected to the first signal path 28. The power supply circuit 24 further comprises a second bias supply 50 that is connected to the second signal path 30. Therein, the first bias supply 48 and the second bias supply 50 are independent of each other.

In an embodiment, the first bias supply 48 comprises a first half-bridge that allows to set a bias voltage for the at least one first diode 32 and the switchable element 20. The second bias supply 50 comprises a second half-bridge that allows to set a bias voltage for the at least one second diode 40.

As the first bias supply 48 and the second bias supply 50 are independent of each other and provided separately, different voltage levels with different timings can be provided to the at least one first diode 32 and the at least one second diode 40.

In an embodiment, the switching circuit 10 described above is operated as follows.

In the on-state of the switchable element 20 or in order to switch the switchable element 20 the on-state, a corresponding DC bias current is applied to the at least one first diode 32 and to the switchable element 20 by the first bias supply 48. Due to the bias current, the switchable element 20 becomes conducting and the RF signal path 12 is closed.

In the off-state of the switchable element 20 or in order to switch the switchable element 20 to the off-state, a corresponding DC bias voltage with opposite polarity may be applied to the switchable element 20. Due to the bias voltage having opposite polarity, the switchable element 20 becomes current-blocking, such that the RF signal path 12 is interrupted.

When switching from the on-state to the off-state, the switchable element 20 can be discharged via the at least one second diode 40.

As the control circuit 22 does not comprise any large energy storages, such as inductors having a large inductance or capacitors having a high capacitance, and due to the possibility to provide a reverse bias pulse to the switchable element 20, the switching circuit 10 described above provides particularly fast switching speeds between the on-state and the off-state and vice versa.

FIG. 2 shows another example embodiment of the switching circuit 10, wherein only the differences compared to the embodiment described above with reference to FIG. 1 are explained hereinafter. In this embodiment, both the first signal path 28 and the second signal path 30 comprise an RF suppressing element 34.

In an embodiment, the RF suppressing element 34 of the first signal path 28 is arranged in a series connection with the at least one first diode 32. In an embodiment, the RF suppressing element 34 of the second signal path 30 is arranged in a series connection with the at least one second diode 40.

The switching circuit 10 described above has a plurality of different fields of application, some examples of which will be described in more detail hereinafter.

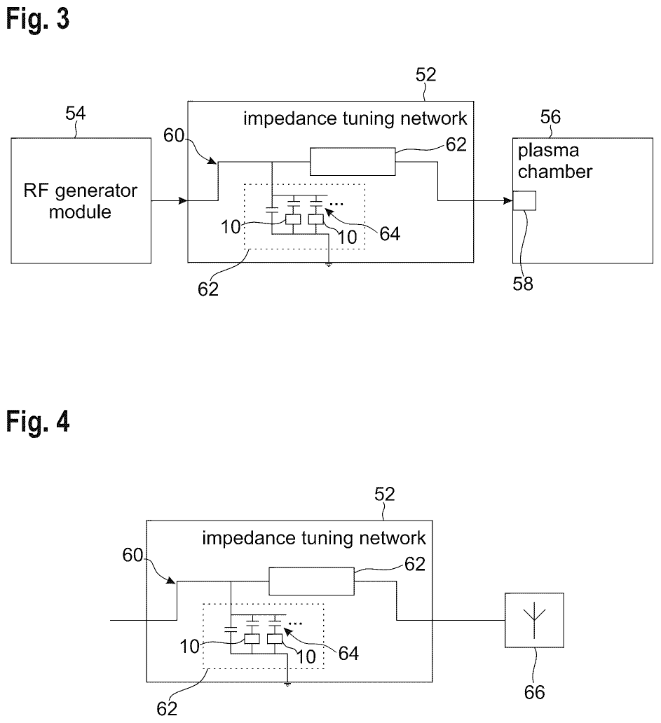

FIG. 3 schematically shows an example of an impedance tuning network 52 for plasma applications. In an embodiment, the impedance tuning network 52 is established as an impedance matching network.

As shown in FIG. 3, the impedance tuning network 52 is provided between an RF generator circuit 54 and a plasma chamber 56 comprising a chamber feed unit 58. For example, the impedance tuning network 52 comprises an RF signal path (“RF bus”) 60 that connects the RF generator circuit 54 to the chamber feed unit 58.

In general, the impedance tuning network 52 is configured to adapt an impedance seen by the RF signal path 60 or connect an impedance into the RF signal path 60, such that a varying impedance of the plasma contained in the plasma chamber 56 is compensated, and such that an optimal load is presented to the RF generator circuit 54, thereby minimizing losses and maximizing the energy fed into the plasma.

In an embodiment, the impedance tuning network 52 comprises at least one impedance tuning circuit 62 that is connected to the RF signal path 60. In general, the at least one impedance tuning circuit 62 is configured to selectively connect at least one reactance to and/or into the RF signal path 60.

In the example embodiment shown in FIG. 3, the at least one impedance tuning circuit 62 comprises a plurality of capacitors 64 as well as a plurality of switching circuits 10 according to any one of the embodiments described above.

In an embodiment, the capacitors 64 can be connected to and/or into the RF signal path 60 individually by the respectively connected switching circuit 10. For example, in the on-state of the respective switchable element 20 of the respective switching circuit 10, the respective capacitor 64 is connected to the RF signal path 60. In the off-state of the respective switchable element 20 of the respective switching circuit 10, the respective capacitor 64 is disconnected from the RF signal path 60.

By selectively connecting or disconnecting the individual reactances to or from the RF signal path 60, respectively, the impedance of the impedance tuning network 52 can be adapted.

FIG. 4 schematically shows an example embodiment of an impedance tuning network 52 for an RF antenna 66. In this embodiment, the impedance tuning network 52 is established as an impedance matching network for an antenna tuner.

In an embodiment, the impedance tuning network 52 is configured to adapt its impedance in order to set desired transmission and/or reception characteristics of the RF antenna 66, namely by selectively connecting at least one reactance to and/or into the RF signal path 60.

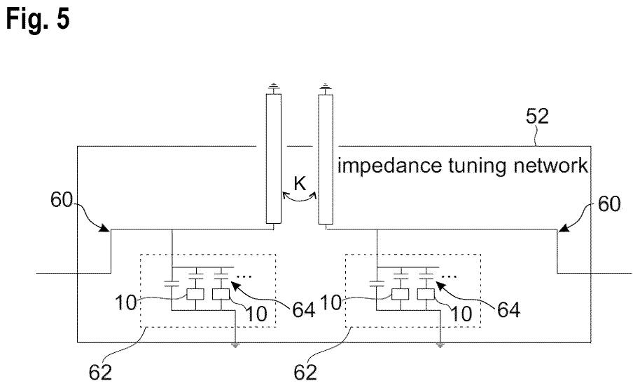

FIG. 5 schematically shows an example embodiment of an impedance tuning network 52 for a tunable filter, for example for a hopping filter employed in frequency hopping techniques. In general, the impedance tuning network 52 is configured to shift the impedance characteristic of the tunable filter to a certain frequency, namely by selectively connecting at least one reactance to and/or into the RF signal path 60. This way, the tunable filter can be set to have a certain pass-band that can pass the tunable filter.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be used synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A switching circuit for selectively closing or interrupting a radio frequency (RF) signal path, comprising:
a switchable element that is switchable between an on-state and an off-state;
a control circuit; and
a power supply circuit,
wherein the control circuit is configured to apply a control signal provided by the power supply circuit to the switchable element, wherein the control signal comprises a control voltage and/or a control current,
wherein the control circuit comprises a first signal path, wherein the first signal path comprises at least one first diode being configured to provide the control signal to the switchable element, and
wherein the control circuit comprises a second signal path, wherein the second signal path is arranged in parallel to the first signal path, wherein the second signal path comprises at least one second diode, wherein the at least one second diode is arranged with opposite polarity compared to the at least one first diode.

2. The switching circuit of claim 1, wherein the control circuit further comprises at least one RF suppressing element, wherein the at least one RF suppressing element is arranged in the first signal path and/or in the second signal path.

3. The switching circuit of claim 2, wherein the at least one RF suppressing element is arranged in the first signal path, wherein the at least one RF suppressing element is arranged in series with the at least one first diode.

4. The switching circuit of claim 1, wherein the control circuit further comprises at least one RF suppressing element, wherein the at least one RF suppressing element is arranged in series with the first signal path and the second signal path.

5. The switching circuit according to claim 1, wherein the first signal path and the second signal path each are to connected to a common connection point, and wherein the switchable element is connected to the common connection point.

6. The switching circuit according to claim 1, wherein the switchable element is a diode.

7. The switching circuit of claim 6, wherein the switchable element is or comprises a PIN diode, a PN-Si diode, or a PN-SiC diode.

8. The switching circuit according to claim 1, wherein the at least one first diode is a PIN diode, a PN-Si diode, or a PN-SiC diode, and/or wherein the at least one second diode is a PIN diode, a PN-Si diode, or a PN-SiC diode.

9. The switching circuit according to claim 1, wherein the first signal path comprises a plurality of first diodes.

10. The switching circuit according to claim 1, wherein the second signal path comprises a plurality of second diodes.

11. The switching circuit according to claim 1, wherein the power supply circuit comprises a first bias supply and a second bias supply, wherein the first bias supply is connected to the first signal path, and wherein the second bias supply is connected to the second signal path.

12. The switching circuit of claim 11, wherein the first bias supply comprises a first half bridge, and/or wherein the second bias supply comprises a second half bridge.

13. An impedance tuning network, wherein the impedance tuning network comprises at least one switching circuit according to claim 1.

14. The impedance tuning network of claim 13, wherein the impedance tuning network comprises at least one impedance tuning circuit, wherein the impedance tuning circuit comprises at least one reactance and the at least one switching circuit, and wherein the at least one switching circuit is configured to selectively connect the at least one reactance to or into a RF signal path of the impedance tuning network.

15. The impedance tuning network of claim 13, wherein the impedance tuning network is established as an impedance matching network.

16. The impedance tuning network of claim 15, wherein the impedance tuning network is established as an impedance matching network for plasma processes.

17. The impedance tuning network of claim 15, wherein the impedance tuning network is established as an impedance matching network for an RF antenna.

18. The impedance tuning network of claim 13, wherein the impedance tuning network is configured to tune an impedance characteristic of a tunable filter.
